(19) United States
(12) Patent Application Publication
(10) Pub. No.: US 2020/0109044 A1
(43) Pub. Date: Apr. 9, 2020

(54) MICROELECTROMECHANICAL MICROPHONE PACKAGE STRUCTURE

(71) Applicant: LINGSEN PRECISION INDUSTRIES, LTD., Taichung City (TW)

(72) Inventors: Chao-Wei YU, Taichung City (TW); Ming-Te TU, Taichung City (TW)

(21) Appl. No.: 16/220,744

(22) Filed: Dec. 14, 2018

(30) Foreign Application Priority Data
Oct. 3, 2018 (TW) 107213410

(51) Int. Cl. B81B 7/00; H04R 1/04; H04R 1/08

(52) U.S. Cl. CPC B81B 7/0038; H04R 1/04; H04R 2201/003; B81B 2201/0257; H04R 1/08

(57) ABSTRACT

The present invention relates to a microelectromechanical microphone package structure which includes a substrate, a metallic cover, an application-specific integrated circuit and a microphone chip. The metallic cover caps the substrate, and a chamber is formed between the metallic cover and the substrate. The application-specific integrated circuit is disposed in the chamber and electrically connected with the substrate. The microphone chip is disposed in the chamber and electrically connected with the application-specific integrated circuit. A filter is disposed between the substrate and the microphone chip and located correspondingly to a sound hole of the substrate, so as to effectively prevent external objects or mists from getting into the chamber through the sound hole, thereby attaining the effect of protecting the microphone chip.

### BACKGROUND OF THE INVENTION

### 1. Field of the Invention

The present invention relates to microelectromechanical microphone package structures and more particularly, to a microelectromechanical microphone package structure capable of blocking external objects from getting thereinto.

### 2. Description of the Related Art

As shown in FIG. 1, the conventional microelectromechanical microphone package structure 1 is primarily provided in a way that a microphone chip 2 and an application-specific integrated circuit 3 are collectively disposed on the top surface of a substrate 4, and then the top surface of the substrate 4 is capped with a metallic cover 5 to locate both the microphone chip 2 and the application-specific integrated circuit 3 in a chamber 6 formed by the substrate 4 and the metallic cover 5, wherein the substrate 4 is provided with a sound hole 7 located correspondingly to the microphone chip 2 to enable the microphone chip 2 to receive sound signal form the exterior through the sound hole 7.

However, in the aforesaid conventional package structure, the sound hole 7 is not provided on the periphery thereof with any structure capable of blocking off external objects or mists, so the external objects or mists may get into the chamber 6 through the sound hole 7, such that the microphone chip 2 and/or the application-specific integrated circuit 3 are liable to be damaged.

### SUMMARY OF THE INVENTION

It is a primary objective of the present invention to provide a microelectromechanical microphone package structure which can effectively prevent external objects or mists from getting thereinto, thereby enhanced in service life.

To attain the above-mentioned primary objective, the microelectromechanical microphone package structure of the present invention includes a substrate, a filter, a microphone chip, an application-specific integrated circuit and a metallic cover. The substrate has a first surface, a second surface opposite to the first surface, and a sound hole penetrating through the first and second surfaces. The filter is disposed on the first surface of the substrate and located correspondingly to the sound hole of the substrate. The microphone chip is piled on the filter for receiving sound signals entering through the sound hole. The application-specific integrated circuit is disposed on the first surface of the substrate and electrically connected with the microphone chip for providing the microphone chip a stable bias voltage required for normal operation and amplifying the sound signals received by the microphone chip for output. The metallic cover is disposed on the first surface of the substrate in a way that the microphone chip and the application-specific integrated circuit are accommodated in a chamber formed between the metallic cover and the substrate.

It can be known from the above description that the microelectromechanical microphone package structure of the present invention uses the filter to effectively prevent external objects or mists from getting into the chamber through the sound hole, so as to protect the microphone chip to attain the effect of enhanced service life.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a schematic sectional view of a conventional microelectromechanical microphone package structure.

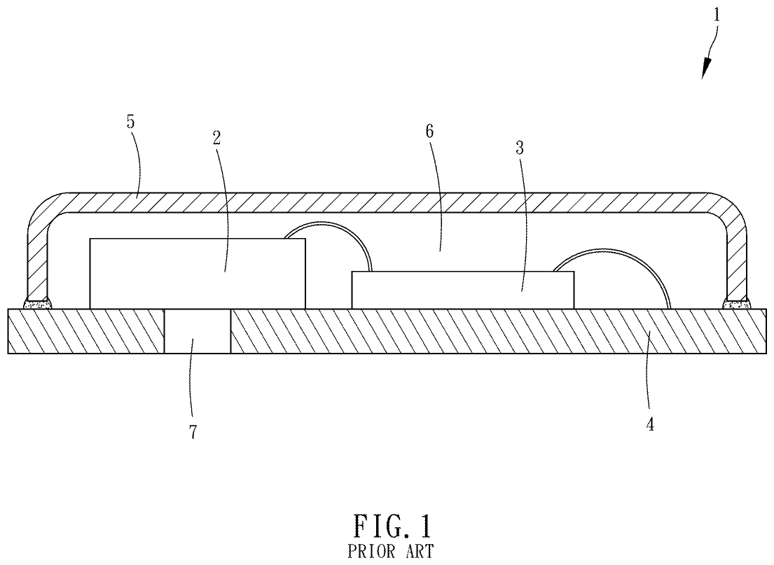

FIG. 2 is a schematic sectional view of a microelectromechanical microphone package structure of the present invention.

FIG. 3 is a schematic planar view of a filter of the microelectromechanical microphone package structure of the present invention.

### DETAILED DESCRIPTION OF THE INVENTION

First of all, it is to be mentioned that same reference numerals used in the following preferred embodiments and the appendix drawings designate same or similar elements or structural features thereof throughout the specification for the purpose of concise illustration of the present invention.

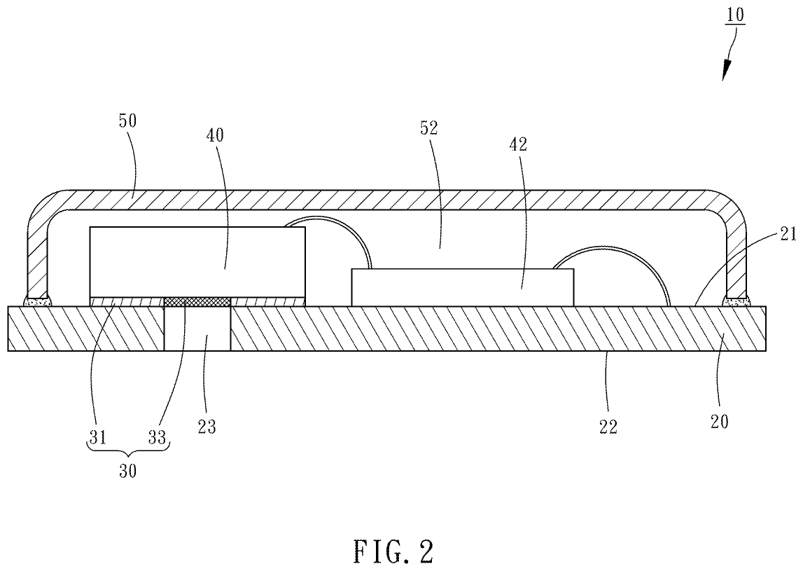

Referring to FIG. 2, the microelectromechanical microphone package structure 10 of the present invention includes a substrate 20, a filter 30, a microphone chip 40, an application-specific integrated circuit 42 and a metallic cover 50.

The material of the substrate 20 may include epoxy, glass fiber, polyphenylene ether (PPE) or ceramic, which is unlimited herein. The substrate 20 has a first surface 21, a second surface 22 opposite to the first surface 21, and a sound hole 23 penetrating through the first and second surfaces 21 and 22.

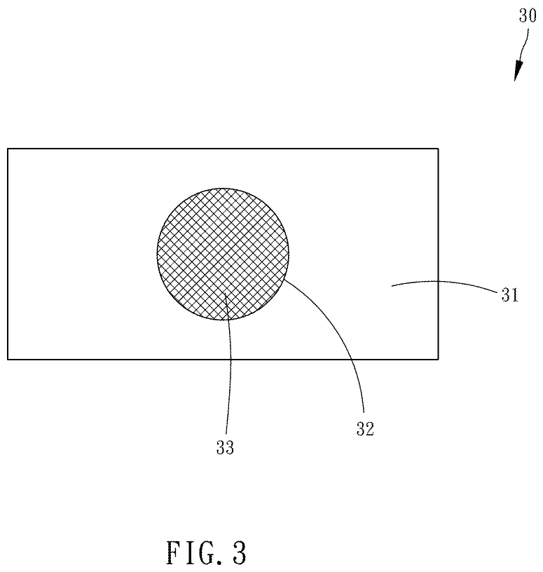

As shown in FIG. 3, the material of the filter 30 in this embodiment includes silicon. The filter 30 has a plate 31 and a filtering mesh 33. The plate 31 is fixed to the first surface 21 of the substrate 20 by adhesive and provided with an opening 32. The filtering mesh 33 is disposed at the opening 32 of the plate 31 and located correspondingly to the sound hole 23 of the substrate 20. Besides, in this embodiment the filtering mesh 33 has an opening size of 5 micrometers or less than 5 micrometers and a thickness of 45 micrometers, wherein the thickness can be modified according to the size of the sound hole 23.

The microphone chip 40 is fixed to a side of the plate 31 of the filter 30 by adhesive and the side faces the opposite direction to the other side facing the substrate 20, so that the microphone chip 40 is adapted for receiving sound signals entering through the sound hole 23.

The application-specific integrated circuit (ASIC) 42 is fixed to the first surface 21 of the substrate 20 by adhesive and electrically connected with the substrate 20 and the microphone chip 40 separately by wire bonding. As a result, on one hand, the application-specific integrated circuit 42 can provide the microphone chip 40 a stable bias voltage required for normal operation; on the other hand, the application-specific integrated circuit 42 can amplify the sound signals received by the microphone chip 40 for output.

The metallic cover 50 is used to provide an electromagnetic shielding effect. The metallic cover 50 is fixed to the first surface 21 of the substrate 20 by adhesive, and a chamber 52 is formed between the metallic cover 50 and the substrate 20 for accommodating the microphone chip 40 and the application-specific integrated circuit 42.

It can be known from the above description that the microelectromechanical microphone package structure 10 of the present invention uses the filter 30 to effectively prevent external objects or mists from getting into the chamber 52 through the sound hole 23, so as to protect the microphone chip 40 to attain the effect of enhanced service life.

What is claimed is:

1. A microelectromechanical microphone package structure comprising:
a substrate having a first surface, a second surface opposite to the first surface, and a sound hole penetrating through the first and second surfaces;
a filter disposed on the first surface of the substrate and located correspondingly to the sound hole of the substrate;
a microphone chip piled on the filter;
an application-specific integrated circuit disposed on the first surface of the substrate and electrically connected with the substrate and the microphone chip; and
a metallic cover disposed on the first surface of the substrate in a way that the microphone chip and the application-specific integrated circuit are accommodated in a chamber formed between the metallic cover and the substrate.

2. The microelectromechanical microphone package structure as claimed in claim 1, wherein the filter has a plate and a filtering mesh; a side of the plate is disposed on the first surface of the substrate; the microphone chip is disposed on another side of the plate; the plate has an opening; the filtering mesh is disposed at the opening and located correspondingly to the sound hole of the substrate.

3. The microelectromechanical microphone package structure as claimed in claim 2, wherein the filtering mesh has an opening size of 5 micrometers or less than 5 micrometers.
